(19) United States
(12) Patent Application Publication
(10) Pub. No.: US 2026/0230032 A1
(43) Pub. Date: Aug. 6, 2026

(54) SELF POWERED BUILDING UNIT

(71) Applicant: Clearvue Technologies Ltd, West Perth (AU)

(72) Inventors: Jamie Lyford, West Perth (AU); Victor Rosenberg, West Perth (AU); Christopher Cole, West Perth (AU)

(21) Appl. No.: 19/447,458

(22) Filed: Jan. 13, 2026

Related U.S. Application Data
(63) Continuation of application No. 17/633,252, filed on May 21, 2020, now abandoned.

(30) Foreign Application Priority Data
Aug. 8, 2019 (AU) 2019902843
Oct. 1, 2019 (AU) 2019903697

(51) Int. Cl. H02S 20/26; H02S 40/22; H02S 40/38

(52) U.S. Cl. CPC H02S 20/26; H02S 40/22; H02S 40/38

(57) ABSTRACT

The present disclosure provides a building unit comprising first and second light transmissive panels. The first panel defines a light receiving surface. The building unit also comprises a structure supporting the panels in a spaced apart relationship to form a cavity therebetween. In addition, the building unit comprises one or more photovoltaic cells disposed within the cavity adjacent the structure. The building unit also comprises an arrangement supported by the structure for re-directing non-visible wavelengths of sunlight incident on or passing through the light receiving surface in a direction generally transverse to a plane of the unit toward structure for collection by the one or more photovoltaic elements. Further, the building unit comprises one or more electrically powered devices within the cavity and arranged to receive electrical power generated by the one or photovoltaic cells.

### TECHNICAL FIELD

The present disclosure relates to a self-powered building unit that is capable of being incorporated in the construction of a building. The building unit may for example take the form of a light transmissive panel or a facade that includes a light transmissive panel.

### BACKGROUND ART

The construction of large buildings such as office towers, high-rise housing and hotels utilise vast amounts of exterior glass panelling and/or facades which incorporate glass panelling.

The present applicant has developed technology that can be incorporated into glass panelling that is able to generate electricity while allowing the transmission of visible light. Such technology is described in the applicant’s international application numbers PCT/AU2012/000778, PCT/AU2012/000787 and PCT/AU2014/000814. In brief these applications disclose a spectrally selective panel that may be used as a windowpane and that is largely transmissive for visible light wavelengths but diverts a large portion of infrared and down converted ultraviolet wavelength light to side portions of the panel where it is absorbed by photovoltaic elements to generate electricity. The disclosed panels are integrated within an integrated glazing unit (IGU) incorporating the photovoltaic elements solar cells or within a window frame, which carries both the panels and the photovoltaic elements solar cells.

### SUMMARY OF THE DISCLOSURE

In broad and general terms this specification discloses a self-powered building unit that is capable of being incorporated in the construction of the building, and in particular as a panel unit that is exposed on one side to the environment and in particular to sunlight. The general idea is to provide a building unit that allows the transmission of visible light into the building and generates own power that can be used to power devices either within the building unit itself or otherwise within the building. For example, and as explained in greater detail later, the building unit may incorporate devices or systems such as a blind, curtain, air damper, fan, sensors, electrochromic layer, motor, or pump. These devices are powered by electricity generated by photovoltaic cells incorporated in the building unit. The devices may be autonomous or remotely controlled. In this regard the building panels can be considered as “smart” in that they can control internal ambience autonomously. For example: internal blind can be automatically deployed when the intensity and/or the angle of incoming sunlight meets certain criteria; or a fan or automated venting can be automatically turned on when temperature or CO or CO₂ levels within or outside of the panel is sensed as exceeding a threshold level.

The building unit also lends itself to incorporation of self-learning technology. For example, the unit may recognise a worker at a desk workstation or desk, for example by facial or gait recognition or other, and learn their preferences for heating, lighting and ventilation.

It is not necessary for the entirety of the building unit to be light transmissive. Indeed, it is envisaged that in many embodiments the building unit in the form of a facade may incorporate a portion which is light transmissive and a portion which is not.

In one aspect there is disclosed a building unit comprising:

first and second light transmissive panels, the first panel defining a light receiving surface;

a structure supporting the panels in a spaced apart relationship to form a cavity therebetween;

one or more photovoltaic cells disposed within the cavity adjacent the structure;

an arrangement supported by the structure for re-directing non-visible wavelengths of sunlight incident on or passing through the light receiving surface in a direction generally transverse to a plane of the unit toward structure for collection by the one or more photovoltaic elements; and

one or more electrically powered devices within the cavity and arranged to receive electrical power generated by the one or more photovoltaic cells.

The building unit may comprise a rechargeable electrical energy storage device electrically connected to the one or more photovoltaic cells.

In a second aspect there is disclosed a building unit comprising:

first and second light transmissive panels, the first panel defining a light receiving surface;

a structure supporting the panels in a spaced apart relationship to form a cavity therebetween;

one or more photovoltaic cells disposed within the cavity adjacent the structure;

an arrangement supported by the structure for re-directing non-visible wavelengths of sunlight incident on or passing through the light receiving surface in a direction generally transverse to a plane of the unit toward structure for collection by the one or more photovoltaic elements; and

a rechargeable electrical energy storage device coupled with the one or more photovoltaic cells wherein the storage device is arranged to power one or more electrically powered devices located inside or outside of the cavity.

In a third aspect there is disclosed building unit comprising:

first and second light transmissive panels, the first panel defining a light receiving surface;

a structure supporting the panels in a spaced apart relationship to form a cavity therebetween;

one or more photovoltaic cells disposed within the cavity and adjacent the structure for producing electrical energy from light passing through the light receiving surface; and

a rechargeable electrical energy storage device coupled with the one or more photovoltaic cells for storing the electrical energy wherein the storage device is arranged to power one or more electrically powered devices located inside or outside of the cavity.

The following introduces optional features of the building unit in accordance with the first, second or third aspect of the present invention.

The rechargeable electrical energy storage device may be a supercapacitor. Alternatively, the rechargeable electrical energy storage device may be a rechargeable battery or a hybrid battery/supercapacitor.

In one embodiment, at least one of the electrically powered devices is located inside the cavity and is operable to vary or otherwise control an effect of solar radiation incident on the light receiving surface.

The one or more electrically powered devices may comprise any one or a combination of any two or more of: a blind, a curtain, an air damper, a fan, an electrochromic, polymer-dispersed liquid crystal (PDLC), LCD, electrophoretic, E-ink or other electrically activated dynamic layer or coating, a motor, a ventilation system, and a pump.

The building unit may comprise a controller arranged to control the operation of one or more of the electrically powered devices. The controller may be arranged for autonomous or remote control.

The building unit may further comprise one or more sensors operatively coupled to the one or more electrically powered devices wherein the sensors are arranged to automatically operate the devices when a threshold level of a sensed parameter is reached or exceeded.

In another embodiment, the building unit comprises one or more sensors operatively coupled to the controller and arranged to provide information to the controller relating to an effect or characteristic of solar radiation passing through the light receiving surface.

The one or more sensors may comprise any one or a combination of any two or more of: a temperature sensor, a light sensor, a rain sensor, an air quality sensor, a CO₂ sensor, a humidity sensor, an ambient light sensor, a battery charge sensor and facial or gait recognition sensor.

One of the electrically powered devices may be a Wi-Fi, cellular/GSM or other communications protocol modem enabling a human to exert control on the operation of one or more of the electrically powered devices.

In one embodiment, the one or more electrically powered devices comprise a blind which is operable between an open condition in which transmission of at least a portion of incident light through the building unit is enabled and a closed condition in which transmission of at least the majority of incident light through the building unit is obstructed by the blind. The blind may comprise portions arranged to obstruct transmission of the light when the blind is in the closed condition and which comprise photovoltaic cells facing towards the light receiving surface when the blind is in the closed condition. Further, the blind may be located inside the cavity between the first and second panels.

Further, the building unit may comprise a building sub-panel coupled with the structure, the sub-panel lying in a plane parallel to the first and second light transmissive panels. The building sub-panel may comprise a sub-panel cavity and the at least one electrically powered devices may be located within the sub-panel cavity. Further, the rechargeable storage device may be located in the sub-panel cavity. The controller may be located in the sub-panel cavity.

The sub-panel cavity may comprise an opaque surface on a same side of the unit as the first panel.

In one embodiment, one or more electrical connectors are arranged to enable electrical coupling between the storage device and an electrically powered device outside of the unit.

The one or more electrically powered devices may comprise one or more light sources located internal of the cavity. The one or more light sources may be arranged wherein light emitted from the one or more light sources is in substance contained within the building unit.

The building unit comprises in one embodiment a suspended coated film positioned between the first and second panels.

In one specific embodiment of the present invention the at least one or one or more photovoltaic cells comprise bifacial photovoltaic cells.

In a fourth aspect there is disclosed a building system comprising:

at least one building unit according to any one of the first, second and third aspects; and

a controller in network communication with the at least one building unit;

wherein the controller is arranged to control operation of one or more of the electrically powered devices of the at least one building unit.

The controller may be arranged to receive sensor data from the one or more sensors and to control operation of one or more of the electrically powered devices of the at least one building unit using the sensor data.

In this embodiment, the controller may be arranged to determine whether the sensor data exceeds a respective threshold level and, if a threshold is exceeded, to automatically send a control signal to one or more of the at least one building unit to modify operation of one or more of the electrically powered devices.

In one embodiment, the controller is in wireless communication with the at least one building unit and is implemented remotely using a cloud computing service platform.

The controller may further be arranged to receive external information and to control operation of one or more of the electrically powered devices of the at least one building unit using the sensor data and the external information. The external information may be associated with weather information and/or occupant preferences.

In one embodiment, the controller is arranged to autonomously control the operation of one or more of the electrically powered devices of the at least one building unit using machine learning.

The building system may comprise a plurality of building units in accordance with any one of the first, second and third aspects of the present invention, wherein the controller is arranged to control operation of one or more of the electrically powered devices of the plurality of building units.

### BRIEF DESCRIPTION OF THE DRAWINGS

Notwithstanding any other forms which may fall within the scope of the system and method as set forth in the Summary, specific embodiments will now be described by way of example only with reference to the accompanying drawings in which:

FIG. 1 is a schematic representation of a light transmissive panel incorporated in an embodiment of the self-powered building unit;

FIG. 2 is a cross-section view of a portion of the light transmissive panel shown in FIG. 1;

FIG. 3a shows a front view of an embodiment of a window comprising an embodiment of the disclosed self-powered building unit;

FIG. 3b shows an end view of the window shown in FIG. 3a;

FIG. 3c shows a side view of the window shown in FIG. 3a;

FIG. 4a is a schematic exploded view of an embodiment of the disclosed self-powered building unit in the form of a building facade of a first configuration;

FIG. 4b is a schematic representation of the unit similar to that disclosed in FIG. 4a viewed from an inside of the building incorporating the facade;

FIG. 4c is a schematic representation of the unit shown in FIG. 4b from an outside of the building incorporating the facade;

FIG. 4d is a view of the unit shown in FIG. 4c but with a cover of a lower sub panel being removed;

FIG. 4e is a view of the unit shown in FIG. 4d but with an internal Venetian blind drawn up;

FIG. 5a is a schematic representation of an embodiment of the disclosed self-powered building unit in the form of a building facade of a second configuration, when viewed from an outside of a building incorporating the facade;

FIG. 5b is an isometric view of the building unit shown in FIG. 5a;

FIG. 5c is a view of the unit shown in FIG. 5a with two sub panel covers being removed;

FIG. 5d is a representation of the unit shown in FIG. 5a when viewed from an inside of a building incorporating the facade;

FIG. 6a is a schematic isometric representation of the disclosed self-powered building unit in the form of a casement window in an open state;

FIG. 6b is a representation of the casement window shown in FIG. 6a when viewed from an inside of the building incorporating the casement window;

FIG. 6c is a representation of the casement window shown in FIG. 6b with a cover portion removed and the window in a closed state;

FIG. 6d is a representation of the casement window shown in FIG. 6c with the window in an open state;

FIG. 7 (a), b) and (c) are representations of portions of a window unit in accordance with embodiments of the present invention; and

FIG. 8 is a block diagram of a building system in accordance with an embodiment.

### DESCRIPTION OF SPECIFIC EMBODIMENTS

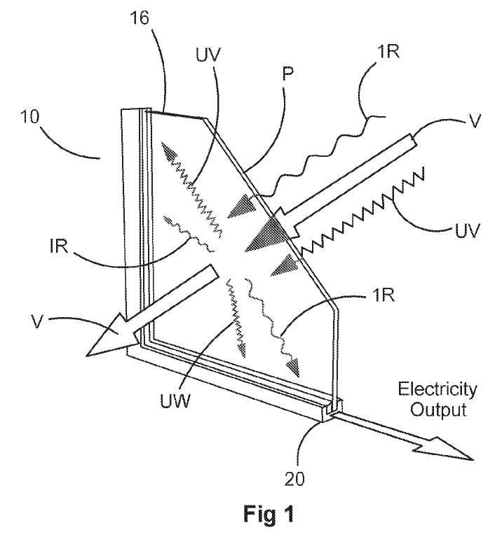

FIGS. 1-3c show a light transmissive and electrical energy generating portion P of one embodiment of the disclosed self-powered building unit 10 (hereinafter referred to in general as “unit 10”). The unit 10 may be configured as or otherwise form a facade for a building. As explained in greater detail later, the unit 10: may be formed so that apart from a structural frame, substantially all the area of the unit is transmissive to natural light; or, may be in the form of an integrated structure having at least one portion which is light transmissive and at least one portion which is not.

The portion P of the unit 10 is arranged to generate electricity for powering devices either within the unit 10 itself or outside of the unit 10. The unit 10 has first and second light transmissive panels 12, 14 respectively with the first panel 12 defining a light receiving surface 12a. A structure in the form of a frame 20 supports the panels 12, 14 in a spaced apart relationship to form a cavity 18 therebetween. One or more photovoltaic elements or cells 26a and 26b (hereinafter referred to in general as “PV cells 26”) are disposed within the cavity 18 adjacent the structure 20. An arrangement 16 is also supported by the structure 20 for re-directing non-visible wavelengths of sunlight incident on or passing through the light receiving surface 12a in a direction generally transverse to a plane of the unit 10 toward the structure 20 for collection by the one or more photovoltaic cells 26. The cavity 18 may contain air, a noble gas such as Xenon or Krypton or be a vacuum.

The above described structure of the light transmissive portion P is utilised in all of the described embodiments. Some of the described embodiments of the unit 10 differ by way of either the type or location of electrical devices powered by the electricity generated by the PV cells 26. For example, and as described later in this specification, in some embodiments the electrical devices are contained within the light transmissive portion P of the unit 10. In other embodiments the electrical devices are contained within a non-light transmissive portion of the unit 10. In other embodiments the electrical devices powered by the generated electricity are located outside of the unit 10. Yet other embodiments may provide a combination of electrical devices powered by the generated electricity where the devices may be internal and external of the unit 10 combining to operate as a self-contained closed system.

Prior to describing these embodiments in greater detail further explanation is provided of the features and functionality of the light transmissive portion P of the unit 10.

The panels 12 and 14 comprise respective panes of glass that are each largely transmissive for visible light. In an embodiment the glass panes that form the panels 12 and 14 may be formed of low iron ultra-clear glass pane with a typical thickness of 4 mm, with the panel 14 additionally having a low-E coating. The first panel 12 defines a planar light receiving surface 12a and in use faces an outside environment e.g. is positioned on a structure facing the outside weather.

In the embodiment of FIGS. 1-3c the arrangement 16 is a laminate structure having three sub-panes 16a, 16b and 16c (hereinafter referred to in general as “panes 16”). Put another way, the arrangement 16 comprises a plurality of panes. A first pane 16a may be formed of low iron ultra-clear glass having a thickness of at least 2mm, typically 4 mm, and second and third panes 16b and 16c are each a layer of ultra-clear glass having a thickness of at least 2mm, typically 4 mm. The panes 16 mate with each other to form a stack with each of the panes substantially parallel to one another. Disbursed between panes 16a and 16b is an interlayer 17a of polyvinyl butyral (PVB) but in some cases could be ethylene-vinyl acetate (EVA) or other suitable material. A PVB interlayer 17b is located between pane 16b and 16c, but PVB interlayer 17b also includes a light scattering element in some embodiments. In some embodiments the light scattering element is a luminescent scattering powder comprising a combination of nano- and micro-metre particles that provides luminescence and also light scattering functions. The arrangement 16 may also include a diffraction grating that is arranged to facilitate redirection of light towards edge region of the arrangement 16 (i.e. towards the frame 20) and guiding of the light by total internal reflection.

The arrangement 16 effectively divides the cavity 18 into two separate cavities 18a, and 18b. The cavity 18a is between the first panel 12 and the arrangement 16. The cavity 18b is between the arrangement 16 and the second panel 14. In the embodiments described later in the specification the electrically powered devices which are located within the unit 10 are most commonly located in the cavity portion 18b. This is the cavity on the side of the arrangement 16 distant the light transmissive surface 12a and the corresponding outward facing first panel 12.

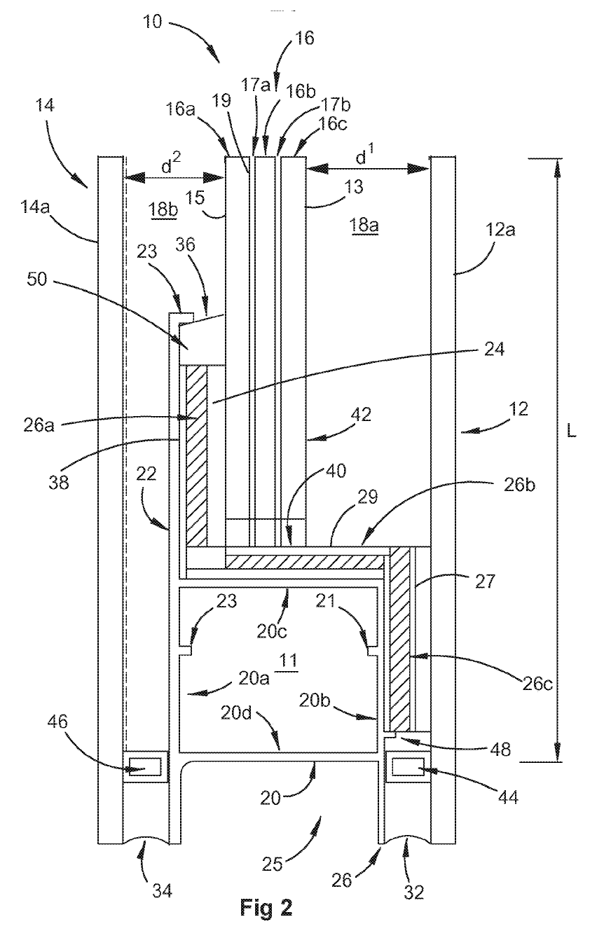

It should be appreciated that the arrangement 16 could have any number of panes with any number of interlayers. In some embodiments the arrangement 16 may comprise a single piece of optically transmissive material such as glass. The arrangement 16 has an end 40 that has a plane which is transverse to the light receiving surface 12a. In the embodiment of FIG. 2, edge 40 is approximately 90° relative to the planar light receiving surface 12a of the first panel 12. The arrangement 16 also has an end region 42 extending substantially parallel to the light receiving surface 12a. End region 42 is a planar region of the arrangement 16 near the end 40.

In an embodiment a distance from the light receiving surface 12a to an outer surface 14a of the second panel 14, that is a thickness of the unit, may be approximately, but is not limited to, 58mm.

In the embodiment of FIG. 2 the support 20 is an extruded aluminium frame having a square tubular section defining a tubular cavity 28. The support 20 could comprise an extruded or pultruded composite material such as carbon fibre or carbon fibre plastic (CFP) or other suitable material. Tubular cavity 28 is defined by a first wall 20a and second wall 20b that are parallel to one another and which are also substantially parallel to the light receiving surface 12a. The tubular cavity 28 also has third wall 20c and fourth wall 20d that are parallel to one another and are transverse to the light receiving surface 12a. The third 20c and fourth walls 20d are substantially parallel to end 40 of arrangement 16. The fourth wall 20d is set inboard from an outer face 26 of the unit 10 to form a channel 25 that is defined by first 20a and second 20b walls. In the embodiment of FIG. 2, a spacing between the first 20a and second 20b walls is approximately 34 mm, and a spacing between third 20c and forth wall 20d is approximately 30 mm. However, a distance that the third 20c and forth 20d walls are spaced apart from one another may be determined by the required depth of the channel 25. The support 20 further comprises tab 21 extending from second wall 20b towards first wall 20a, and tab 23 extending from first wall 20a towards second wall 20b. The support 20 also has an outwardly open channel 25 that surrounds the wall 20d of the support 20.

The support 20 has a flange 22 extending into the second cavity 18b in a direction substantially parallel to the light receiving surface 12a. In the embodiment of FIG. 2 the flange 22 is formed as a continuation of the first wall 20a. However, in some embodiments flange 22 extends from third wall 20c into the second cavity 18a. Generally, the flange is positioned relative to the arrangement 16 on a side opposite the light receiving surface 12a. In some embodiments the flange 22 extends beyond the third wall 20c and into the cavity 18b by approximately 39 mm. In the embodiment of FIG. 2, the arrangement 16 may be spaced from the flange 22 by approximately 6 mm.

In the embodiment of FIGS. 1-3c the first photovoltaic cell or element 26a is sandwiched between the flange 22 and end region 42 of the arrangement 16 at a first orientation that is approximately parallel to the light receiving surface 12a. A flexible PCB 38 is positioned between the first photovoltaic element 26a and the flange 22. A transmissive spacer in the form of cover 24 is positioned between the arrangement 16 and first photovoltaic cell 26a in some embodiments. In an embodiment the cover 24 may have a thickness of approximately 3 mm. The first photovoltaic element 26a and cover 24 are held in place relative one another at an edge region of the arrangement 16. The arrangement 16 is secured to the flange 22 by adhesive portion 36. In an embodiment the adhesive portion is window silicone. To prevent the adhesive portion 36, the first photovoltaic element 26a and the cover 24 from sliding out of position, the flange 22 has a lip 23 that extends towards the arrangement 16 thereby narrowing a cavity opening compared to a cavity formed between the flange 22 and the arrangement 16. The lip 23 is not required in all embodiments. In an embodiment the first photovoltaic element 30 may have a width of approximately 30 mm extending away from the third wall 20c along the flange 22.

A second photovoltaic cell/element 26b is positioned on the third wall 20c so that a portion of the second photovoltaic element 26b is sandwiched between the end 40 of the arrangement 16 and the third wall 20c. The second photovoltaic element 26b is oriented transversely to the light receiving surface 12a. In this way, the second photovoltaic element 26b is in a second orientation that is different to the first orientation of the first photovoltaic element 30. A width of the second photovoltaic element 26b extending in a direction from the first wall 20a to second wall 20b is dependent on a distance from the flange 22 to the second wall 20b. In an embodiment the second photovoltaic element 26b may have a width of approximately 27 mm. In an embodiment the second photovoltaic element 26b has a silicone encapsulant e.g. layer 29. A flexible PCB is positioned between the second photovoltaic element 26b and the third wall 20c.

The embodiment shown in FIG. 2 also has a third photovoltaic cell/element 26c. However, the third photovoltaic element 26c is not required in all embodiments. The third photovoltaic element 26c is positioned on the second wall 20b between the support 20 and the first panel 12. In the embodiment of FIG. 2 an air gap is formed between the third photovoltaic element 26c and first panel 12. The use of an air gap helps to minimise conduction of heat. Therefore, in such embodiments, the unit 10 may be arranged to form an integrated glass unit.

To prevent movement of the third photovoltaic element 26c in a direction along a plane defined between the third 20c and fourth 20d walls (i.e. along the plane defined by second wall 20b towards edge 26), a foot 48 extends from the second wall 20b towards the first panel 12. However, the foot 48 is not needed in all embodiments and the third photovoltaic element 26c can be secured to the support 20 by adhesives. Like the second photovoltaic element 26b, the third photovoltaic element 26c has a silicone encapsulant.

A flexible PCB is positioned between the third photovoltaic element 26c and the second wall 20b. In some embodiments, a single flexible PCB is provided and is fixed to the flange 22, the third wall 20c and the second wall 20b in a continuous manner so that each of the first 26a, second 26b and third 26c photovoltaic elements are in contact with the single flexible PCB. In an embodiment the third photovoltaic element 26c may have a width of approximately 30 mm extending away from the foot 48 along the second wall 20b into the cavity 18.

In the present embodiment, each of the photovoltaic cells/elements is of the same type. However, it should be appreciated that the photovoltaic cells/elements may include elements that are of different types. For example, the photovoltaic elements may comprise different respective semiconductor materials, such as Si, CdS, CdTe, GaAs, CIS or CIGS or any other suitable semiconductor material.

The first panel 12 is connected to the support 20 by an adhesive portion 32. In some embodiments the adhesive portion 32 acts as a seal to prevent ingress of an outside environment into the cavity 18a. The adhesive portion 32 also helps to thermally insulate the support 20 from the first panel 12. In some embodiments the adhesive portion 32 is window silicone. Similarly, the second panel 14 is connected to the support by the adhesive portion 34 that in some embodiments acts as a seal to prevent ingress of an outside environment into cavity 18b. The adhesive portion 34 also helps to thermally insulate the support 20 from the second panel 14. In some embodiments the adhesive portion 34 is window silicone. When adhesive portions 32 and 34 form a seal, the cavity can be considered as being closed or sealed to an outside environment. To prevent condensation of any moisture that may be present in the cavities 18a and 18b, a desiccant 44 may be positioned in the first cavity 18a proximate the adhesive portion 32, and a desiccant 46 may be positioned in the second cavity 18b proximate the adhesion portion 34.

The support 20 with the continuous channel 25 surrounds portions of the unit 10 and is generally shaped such that the unit 10 may be positioned into a standard window frame providing a triple-glazing arrangement.

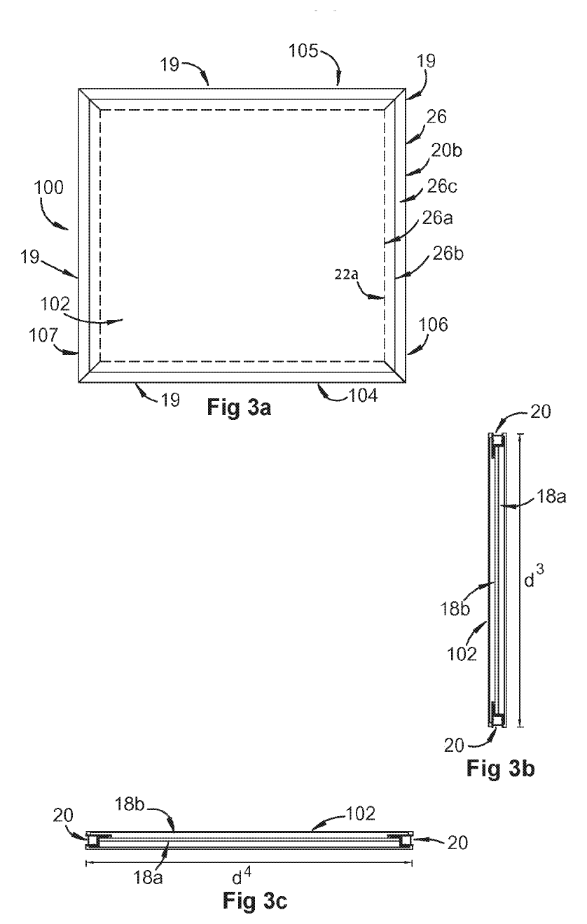

FIGS. 1-3c shows the unit 10 forming a window element 102 arranged to fit into a window frame. The support 20 extends around a perimeter of the window element 102. FIG. 3a shows a view towards the first panel 12 at an angle transverse to the plane defined by the light receiving surface 12a. The end of the flange 22 is depicted by dashed line 22a. The first photovoltaic element 26a is positioned proximate end of flange 22a, and the third photovoltaic element 26c is positioned on the second wall 20b proximate the end 26 of support 20. FIG. 3b shows a cross-sectional view of unit 10 extending along a line extending from side 106 to 107.

FIG. 3c shows a cross-sectional view of the portion P of unit 10 extending along a line extending from side 104 to 105. In the embodiment of FIG. 3b a width (d⁴) of the element 100 may be 1087 mm and a height (d³; see FIG. 3c) may be 1200 mm. However, the height and width of the unit 10 varies depending on the required size of window element 102 and in principle the unit 10 can have any size.

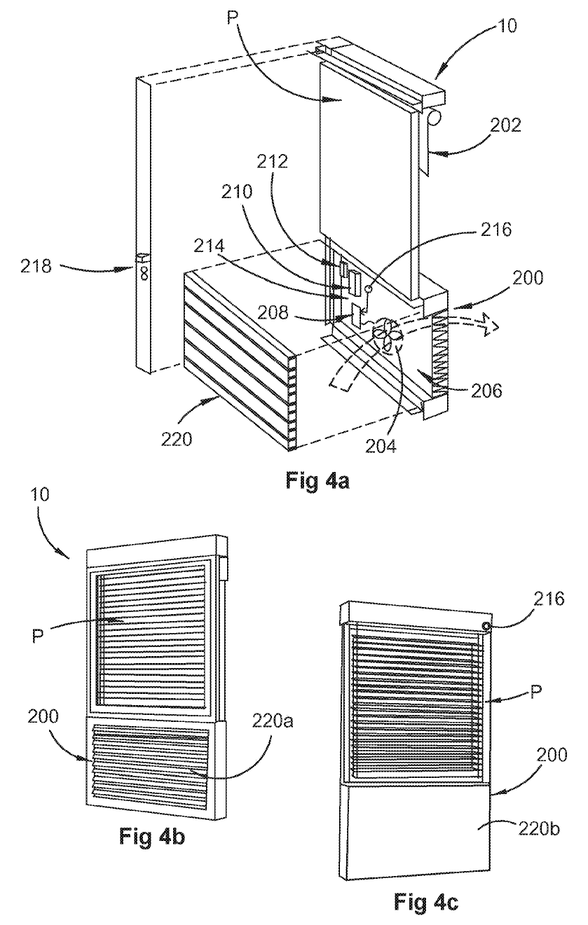

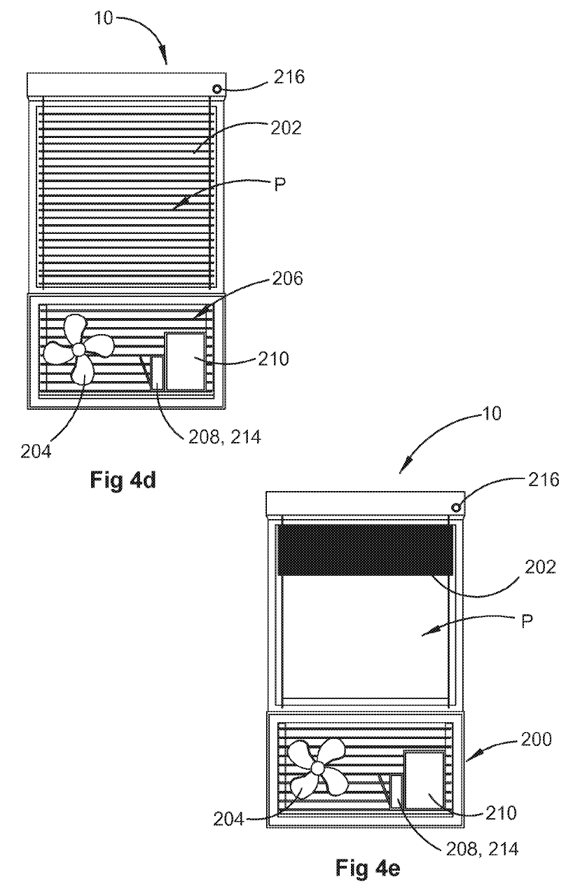

FIGS. 4a-4c depict an embodiment of the unit 10 in the form of a building facade. The unit 10 incorporates a light transmissive panel P which may have the features described above in relation to the embodiment shown in FIGS. 1-3c, and optionally one or more internal electrically powered devices together with a non-light transmissive (i.e. opaque) sub-panel 200. The light transmissive panel P and the subpanel 200 are connected together to form a single building facade unit 10 that can for example be handled, lifted, and fitted as a single unit.

In this particular embodiment the electrically powered devices incorporated in the unit 10 may include any one, or any combination of two or more, of:

a blind 202 (in this Fig a roller blind) which would be located in the cavity 18 and more particularly the cavity 18b,

a fan 204 which is located in the cavity 206 of the sub- panel 200,

a main processor 208 also located within the cavity 206,

an electrical energy storage device 210 which may be in the form of a rechargeable battery, a supercapacitor or banks of capacitors, located in the cavity 206,

an electrical power conditioning system 212 which may be in the form of for example an inverter and/or voltage or current regulators, located in the cavity 206,

a Wi-Fi or cellular/GSM modem 214 in the cavity 206,

and at least one sensor 216.

The blind 202 is operable between an open condition in which transmission of a portion of incident light through the building unit is enabled and a closed condition in which transmission of incident light through the building unit is obstructed by the blind 202. The blind 202 is shown in the open condition in FIG. 4e and in the closed condition in FIG. 4d. The blind 202 comprises portions that have photovoltaic cells (not shown) facing towards the light receiving surface when the blind is in the closed condition. The blind 202 can consequently absorb incident light and generate electricity when in the closed condition.

It should be understood that other electrically powered devices or indeed other non-electrically powered devices may be incorporated in the unit 10 either in the light transmissive panel P or the subpanel 200.

Examples of other electrically powered devices include:

a pump

an electrochromic, polymer-dispersed liquid crystal (PDLC), LCD, electrophoretic, E-ink or other electrically activated dynamic layer or coating formed on for example the second panel 14

light sources including LEDs integrated within the panel P or within the frame surrounding panel P

smoke detectors

visual displays including for displaying video content

speakers

microphones

cameras

a ventilation system, which may be a fan-based ventilation system, a heat-recovery ventilation system, or a natural ventilation system and may include a natural ventilation damper.

louvers

louvers comprised of or incorporating active photovoltaic material

heater

refrigeration unit

motors

antennas

communications receivers and amplifiers, e.g. digital radio, TV

awnings

curtains

Examples of types of sensors that may be incorporated in the unit 10 include heat (i.e. temperature) sensors, light sensors/detector, rain sensors, air quality sensors (particulate matter sensors or gas sensors such as CO or CO₂ sensors), ambient light sensors, humidity sensors (which may be optical, capacitive, resistive or piezo-resistive), pressure sensors, battery charge sensors, facial or gait recognition sensors. At least some of the sensors may communicate via Wi-Fi, Bluetooth, Zigbee, Z-wave, Decawave or other networking methods or protocols .

When the electrically powered device is a light source, the light source may be located in the frame 20 and arranged to illuminate the laminate structure 16. The light source may for example be in the form of one or more LED diffusing strips mounted within the frame 20 or may take any other suitable form. The light produced by the light source may be scattered: through at least one of the three sub-panes 16a, 16b and 16c; between any two mutually adjacent sub-panes 16a, 16b and 16c; or, by a light scattering layer on any one of the three sub-panes 16a, 16b and 16c, or between any two mutually adjacent sub-panes 16a, 16b and 16c. If a light scattering layer is used, this may be one of the PVB interlayers 17a and 17b. Alternately or additionally a light scattering layer may be provided on one or both of the light transmissive panels 12 and 14. The light source may be arranged to illuminate the laminate structure 16 from one or more edges. The light source may also be arranged to produce multiple different light wavelengths so that the colour of the panel P can be varied. The wavelengths may also be user selectable and/or programmable remotely for example via Wi-Fi, Bluetooth, Zigbee, Z-wave, Decawave or other networking methods or protocols and the processor of the unit 10.

The light source may be used to colour the panel 10 by having the light in substance contained within the unit 10, i.e. between the light transmissive panels 12 and 14. This can occur when a pane 16a, 16b, 16c, layer 17a, 17b, or panel 12, 14 into which the light from the source is transmitted acts as a waveguide. This may be particularly effective at night time and could be used to produce various visual effects or for advertising purposes. The same or an alternate light source may be operated to provide internal lighting for a building incorporating the unit 10.

An example of a non-electrically powered device that may be incorporated in the unit 10 is a heat exchanger for example through which the liquid can be pumped to absorb or transfer heat from air within the unit 10A.

Electrical connecters 218 including but not limited to USB sockets, phone type jacks, RCA connectors and SMA connectors may be located on or accessible from a surface of the unit 10 internal of building. The connectors 218 may be connected to different devices or systems within the unit 10 for example, the electrical energy storage device, antenna, communications receiver.

The subpanel 200 may be formed with removable covers 220a, 200b on opposite sides. In this embodiment the cover 220a accessible from an inside of a building constructed using the unit 10 is in the form of a louvre panel. This provides access to the interior of the subpanel 200 and the devices and systems accommodated therein. The cover 220b accessible from outside of the building in the form of an opaque sheet which may for example be made from aluminium or a composite material.

The electrical devices within the unit 10 may be arranged to operate autonomously or can be remotely controlled. The remote control can be provided as an alternative to a fully autonomous unit 10, or to provide a user with the ability to override the otherwise autonomous systems within the unit 10.

It should be appreciated that because each unit 10 is self-powered by virtue of the PV cells 26 and the energy storage device 210, use of the unit 10 in the construction of a building can provide substantial savings as it avoids the need for many electrical and control connections and wiring.

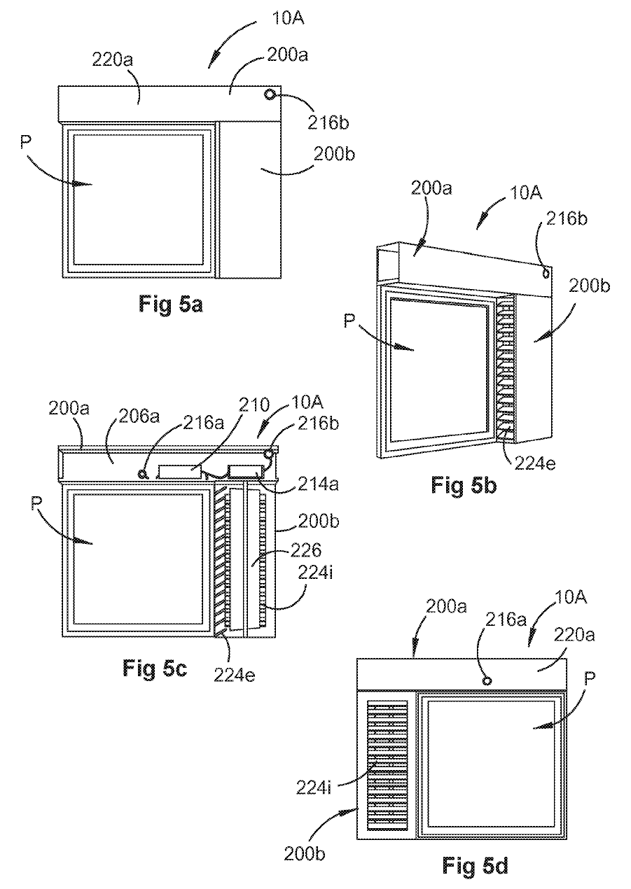

FIGS. 5a-5d depict a further embodiment of the disclosed self-powered building unit, which for ease of differentiation is noted as a unit 10A. This embodiment of the unit 10A differs from the embodiment of the unit 10 shown in FIGS. 4a-4e only in terms of its geometry/configuration and the types of electrically powered devices incorporated in the unit 10A.

The unit 10A comprises two subpanels, namely subpanel 200a on top of the panel P and subpanel 200b on the left-hand side of the panel P when the unit 10A is viewed from an outside of the building in which it is installed (shown in FIGS. 5a-5c). The subpanel 200a has a cavity 206a which includes a CO₂ sensor 216a, a rain sensor 216b, a Wi-Fi enabled automatic controller 214a, and rechargeable power storage unit in the form of a battery or supercapacitor 210. The cavity 206a is closed on the exterior side of the unit 10A by an opaque cover 220a. In this embodiment panel P may include an electrochromic, polymer-dispersed liquid crystal (PDLC), LCD, electrophoretic, E-ink or other electrically activated dynamic layer or coating for example on the inside of the surface of panel 14 to enable autonomous or remote-control change of the opacity of the panel and thereby enable change of the intensity and/or colour of light transmitted through the panel P.

The subpanel 200b includes a set of louvres 224e on the exterior of the unit 10A with reference to its installation in a building, a motorised natural ventilation damper 226 housed in an internal cavity 206b, and a set of louvres 224i on the interior of the unit 10A with reference to its installation in a building. The exterior facing side of the subpanel 200b is provided with an opaque cover 220b.

In use controller 214a may be programmed so that when the rain sensor 216b detects rain the controller 214a operates the damper 226 to close blocking rain from entering

the building through the unit 10A. The intensity and/or colour of light transmitted through the panel P be controlled again by the controller 214a either autonomously having regard to the sensed intensity of sunlight and angle of incidence panel P or remotely by a worker via a website, mobile phone app or laptop GUI connected by Wi-Fi or other communications protocol to the controller 214a.

The unit 10A (and indeed all embodiments of the unit 10) may also incorporate within the Wi-Fi enabled automatic controller 214a, or associated processor, artificial intelligence/self-learning capability. This will enable the unit 10/10A to automatically adjust various controllable aspects such as lighting, light transmission characteristics (e.g. electrochromic or electrophoretic layer or coating, or blind settings) and ventilation control to worker/occupant preferences. In this event the unit 10/10A includes the ability to recognise a worker/occupant for example by way of facial or gait recognition, thumbprint, iris scan, voice or any combination thereof.

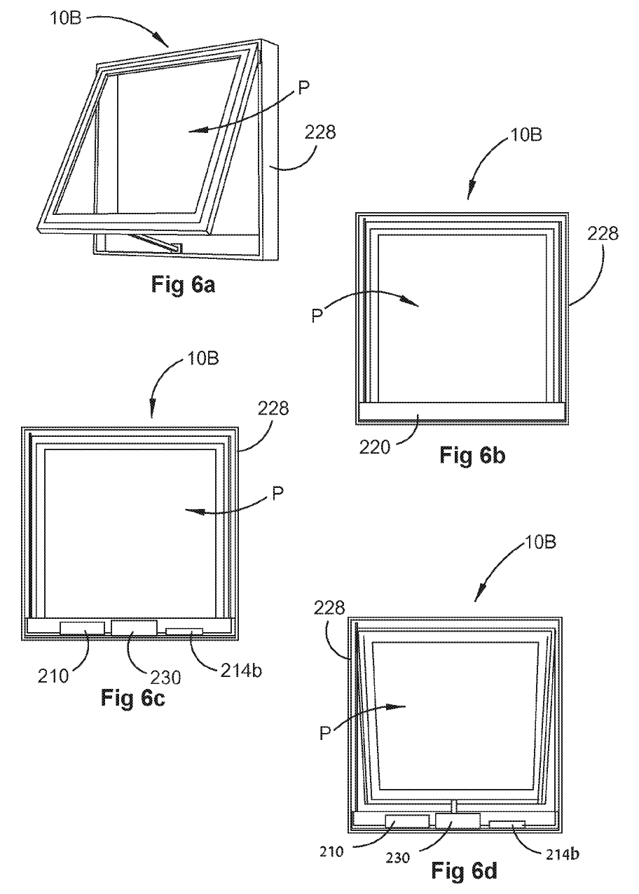

FIGS. 6a-6d depict a further embodiment of the disclosed self-powered building unit, which is in the form of a self-powered automatic casement window 10B. The window 10B and comprises an outer casement 228 in which the panel P is fitted. Also provided within the casement 228 is a motor 230, Wi-Fi enabled processor/controller 214b, and electrical power storage device in the form of a battery or supercapacitor 210 that receives electricity from the PV cells within the panel P. The panel P can be swung open and closed from the casement 228 either autonomously or by remote control. Rain sensing and learning algorithms can automatically open and close the window according to weather conditions and/or occupant preferences. The casement windows 10A can be easily retrofitted into existing structures.

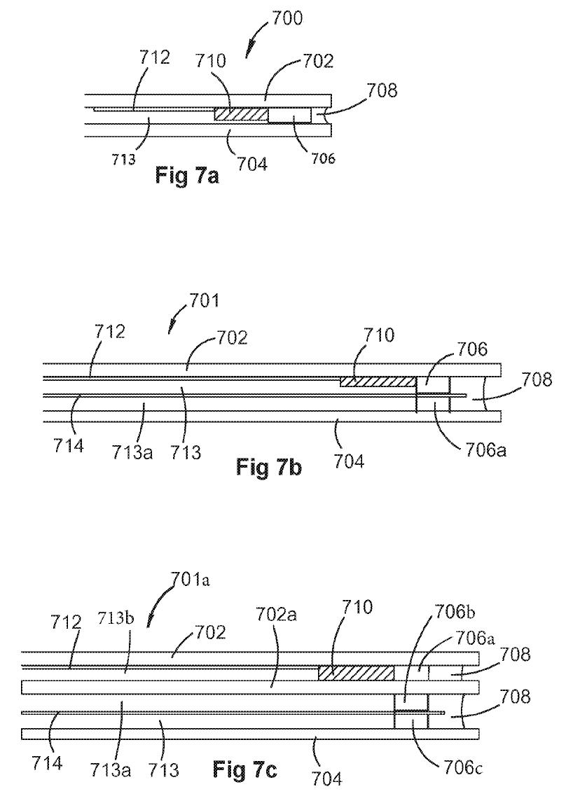

FIG. 7 (a) illustrates another embodiment of the self-powered building unit. FIG. 7 (a) shows a window panel 700 comprising a top panel 702 and a bottom panel 704. The top panel 702 and the bottom panel 704 are spaced apart by a spacer 706 and a cavity 713 that is filled with air, a noble gas such as Xenon or Krypton or is a vacuum between the top panel 702 and the bottom panel 704 is sealed using a silicone-based compound 708. In a preferred embodiment bottom panel 704 has at least one low-emissivity coating. The self-powered building unit 700 comprises at least one series of bi-facial solar cells 710 positioned along an edge portion of the window panel 702. Further, the self-powered building unit 700 includes in this embodiment an electrically powered device which is provided in the form of a layer 712 that has dynamically switchable light transmissivity properties. For example, the layer may be switchable from an opaque state to a non-scattering transparent state or various in-between states of shading or tinting. The layer is in this embodiment is an electrochromic layer but may alternatively also be a polymer-dispersed liquid crystal (PDLC), LCD, electrophoretic, E-ink, a suspended particle device (SPD) or another electrically activated dynamic layer.

FIG. 7 (b) illustrates another embodiment of the self-powered building unit. FIG. 7 (b) shows a window panel 701 comprising a top panel 702 and a bottom panel 704. The top panel 702 and the bottom panel 704 are spaced apart by spacers 706 and 706a and cavities 713 and 713a are filled with air, or in a preferred embodiment are filled with a noble gas such as Xenon or Krypton or employ a vacuum between the top panel 702 and the bottom panel 704 is sealed using a silicone-based compound 708. In a preferred embodiment the bottom panel 704 has at least one low-emissivity coating. The self-powered building unit 701 comprises at least one series of bi-facial solar cells 710 positioned along an edge portion of the window panel 702. Further, the self-powered building unit 701 includes in this embodiment an electrically powered device which is provided in the form of a layer 712 that has dynamically switchable light transmissivity properties. For example, the layer may be switchable from an opaque state to a non-scattering transparent state or various in-between states of shading or tinting. The layer in this embodiment is an electrochromic layer but may alternatively also be a polymer-dispersed liquid crystal (PDLC), LCD, electrophoretic, E-ink, a suspended particle device (SPD) or another electrically activated dynamic layer. Further, the self-powered building unit 700a includes in this embodiment a suspended coated film 714. The suspended coated film 174 may be selected to maximise or minimise solar heat gain through the self-powered building unit. In this embodiment, the suspended coated film 714 has coatings to at least one major surface and the coatings are selected to reflect both a portion of IR radiation and a portion of UV radiation.

FIG. 7 (c) illustrates another embodiment of the self-powered building unit. FIG. 7 (c) shows a window panel 701a comprising a top panel 702, an intermediate panel 702a and a bottom panel 704. The top panel 702 and the intermediate panel 702b are spaced apart by spacer 706a and a formed cavity is sealed using a silicon compound 708. The intermediate panel 702a and the bottom panel 704 are spaced apart by spacers 706b, 706c and a silicone compound 708 seals a formed cavity. Cavities 713, 713a and 713b are filled with air, or in a preferred embodiment are filled with a noble gas such as Xenon or Krypton or employ a vacuum between the intermediate panel 702a and the bottom panel 704. The bottom panel bottom panel 704 has a low-emissivity coating. A series of bi-facial solar cells 710 is positioned along each edge portion of the window panel 702. Further, the self-powered building unit 701a includes in this embodiment an electrically powered device which is provided in the form of a layer 712 that has dynamically switchable light transmissivity properties. The layer may be switchable from an opaque state to a non-scattering transparent state or various in-between states of shading or tinting. The layer in this embodiment is an electrochromic layer but may alternatively also be a polymer-dispersed liquid crystal (PDLC), LCD, electrophoretic, E-ink, a suspended particle device (SPD) or another electrically activated dynamic layer. Further, similar to the building unit 701 described with reference to FIG. 7(b), the self-powered building unit 701a includes a suspended coated film 714. The suspended coated film 714 has coatings to at least one major surface and the coatings are selected to reflect both a portion of IR radiation and a portion of UV radiation.

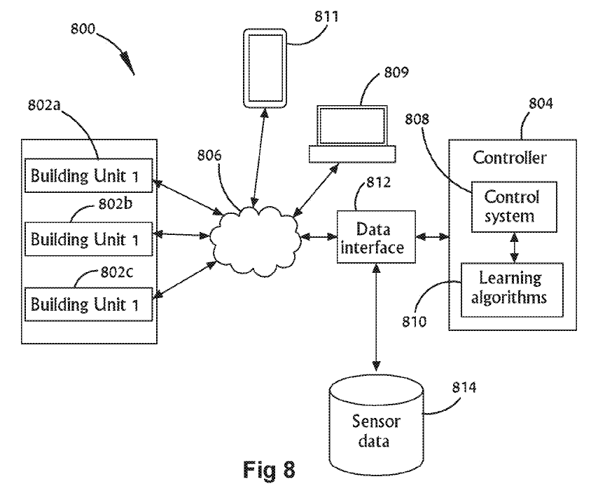

FIG. 8 illustrates a building system 800 in accordance with a further embodiment wherein one or more building units, for example according to the above described embodiments, can be remotely controlled in response to user action, or autonomously, for example using machine learning / artificial intelligence based on information received from one or more sensors of the building units, external information such as weather information, and/or occupant preferences.

In the present example, the system 800 comprises three self-powered building units 802a, 802b, 802c, each of the self-powered building units 802a, 802b, 802c being provided in accordance with the above described embodiments, and a controller 804 that is in network communication with the three self-powered building units 802a, 802b, 802c. The controller 804 is arranged to remotely control operation of one or more electrically powered devices of the building units 802a, 802b, 802c.

In a specific embodiment, the controller 804 is implemented remotely using a cloud computing service platform such as using an Linux server on Amazon Web Services (AWS), the controller 804 being in wireless communication with the three building units 802a, 802b, 802c through a wide area network such as the Internet 806 and a local wireless network that connects the building units 802a, 802b, 802c to the Internet.

The controller 704 is implemented using a control system 808 arranged to manage control of the building unit electrically powered devices and to provide a user interface that is accessible using any suitable computing device, such as a personal computer 809 and a smartphone 811. The control system 808 in this example is arranged to control the building unit electrically powered devices in response to instructions received directly from a user, for example using a personal computer 809 or a smartphone 811, and to autonomously control the building unit electrically powered devices based on defined criteria such as one or more thresholds, or using machine learning / artificial intelligence.

In this example, the controller 804 is able to control the building unit electrically powered devices using at least one learning algorithm 810 that receives data from sensors on the building units, external information such as weather information, for example from a 3^{rd} party provider, and user preferences, and in response produces control instructions to the building unit electrically powered devices, for example that cause adjustment of the opacity of the panel of at least one building unit and/or the position of the blinds of at least one building unit.

In the present example, the control system 808 is implemented using a Node-RED programming interface, and the learning algorithm is a deep-Q Reinforcement Learning (RL) algorithm such as a deep deterministic policy gradient (DDPG) algorithm, although it will be understood that other implementations are envisaged.

It should also be understood that although the present embodiment includes three building units 802a, 802b, 802c, the system 800 may comprise any other number of building units such as one building unit only, or more than three building units.

The system 800 also includes a data interface 812 that in this example is also implemented using a cloud service such as provided by Amazon Web Services (AWS). The data interface 812 acts as a broker between the building units 802a, 802b, 802c and the remote controller 804 in that the data interface 812 facilitates communication of encrypted lightweight protocol messages between the building units and the control system 808. In this example, the data interface 812 uses Message Queuing Telemetry Transport (MQTT) protocol, although it will be understood that any suitable communication protocol is envisaged.

The data interface 812 also manages storage of sensor data 814 received from the sensors, in this example at the cloud service platform.

In the illustrated in FIG. 8, the sensors of the building units 802a, 802b, 802c are Wi-Fi enabled, for example by providing each building unit with a Wi-Fi interface.

In the present example, the sensors 216 in each building unit include a CO₂ sensor, rain sensor, temperature sensor, light sensor/detector, ambient light sensor, air quality sensor, humidity sensor, and/or facial or gait recognition sensor, although it will be understood that any suitable sensor is envisaged.

The sensors 216 in the building units sense respective parameters associated with the sensors, and signals indicative of the sensed parameters are sent by Wi-Fi or other communications protocol and the Internet 806 to the data interface 812 for storage at the cloud server. The controller 804 then accesses the stored sensor data 814 and based on the sensor data 814 makes determinations as to whether to make any changes to the building unit electrically powered devices. For example, the controller 804 may make determinations based on whether the sensor data exceeds a respective threshold level set using the interface of the control system 808 and, if a threshold is exceeded, to automatically send a control signal to one or more building units to modify one or more of the electrically powered devices.

It will be appreciated that instead of implementing the controller 804 and the data interface 812 at a cloud server, and storing the sensor data 814 at the cloud server, the controller 804 and the data interface 812 may be implemented using any suitable remote network-enabled computing device, with the sensor data 814 for example stored at the computing device.

The user interface of the control system 808 may include a dashboard that is presented to a user when the user accesses the control system 808 using a computing device. The dashboard may be used to directly control the building unit electrically powered devices either individually or in selected groups, to set thresholds to be used to automatically control the building unit electrically powered devices, and to set parameters to be used by the machine learning algorithm(s) 810. For example, machine learning setpoints may be defined for the desired temperature in a room, the desired room humidity, or maximum CO or CO₂ level.

The dashboard may also display information indicative of the currently applicable sensor data, such as for example the current temperature adjacent a building unit, the current wind speed adjacent the building unit, and information indicative of the status of one or more of the building unit electrically powered devices, such as the current opacity level, the current blind position, and so on.

In a specific example, the dashboard of the control system 808 may be used to set a room temperature setpoint of 23ºC. When the temperature sensor senses a temperature that is determined by the controller 804 to be either higher or lower than 23ºC, the control system 808 uses the learning algorithm 810 to generate and send control instructions to particular building unit electrically powered devices to cause the temperature to move closer to the desired setpoint. For example, the ventilation system of one or more of the building units 802a, 802b, 802c may be turned on, up or down, the opacity of one or more of the building units 802a, 802b, 802c modified, and/or one or more of the blinds of one or more of the building units 802a, 802b, 802c opened or closed a specific amount.

In the present embodiment, the learning algorithm is a Reinforcement Learning (RL) type of algorithm wherein the algorithm is trained using a reward function, although it will be understood that other arrangements are possible. In the present example, after actioning one or more electrically-powered devices, and depending on whether the sensor data subsequently received by the controller 804 constitutes a positive reward or a negative reward, the controller 804 progressively learns how to effectively actuate the one or more electrically-powered devices in order to control the internal temperature of the room.

In a particular example wherein one or more building units is equipped with a battery charge sensor and the controller 804 receives battery charge sensor data indicative that the battery level is low, the controller 804 may further be arranged to control operation of the one or more electrically-powered devices to remain in one specific state in order to conserve power, and the controller 804 may be arranged to automatically reduce the learning algorithm reward in these circumstances.

Whilst a number of specific embodiments have been described, it should be appreciated that the disclosed unit 10 may be embodied in many other forms. For example, the light transmissive and power generating portion P of the unit 10 may have configurations other than rectangular. Also, the arrangement 16 incorporated in the unit to direct infrared and ultraviolet radiation laterally towards the frame 20 need not comprise three layers described and illustrated herein and may for example be formed with a single layer. The portion P could take for example the form described in any one PCT/AU2012/000778, PCT/AU2012/000787 and PCT/AU2014/000814 the contents of which are incorporated herein by way of reference.

Any discussion of the background art throughout this specification should in no way be considered as an admission that such background art is prior art, nor that such background art is widely known or forms part of the common general knowledge in the field in Australia or worldwide.

In the claims which follow and in the preceding description, except where the context requires otherwise due to express language or necessary implication, the word “comprise” and variations such as “comprises” or “comprising” are used in an inclusive sense, i.e. to specify the presence of the stated features but not to preclude the presence or addition of further features of the embodiments as disclosed herein.

What is claimed is:

1. A building unit comprising:
first and second light transmissive panels, the first panel defining a light receiving surface;
a structure supporting the panels in a spaced apart relationship to form a cavity therebetween;
one or more photovoltaic cells disposed within the cavity adjacent the structure;
an arrangement supported by the structure for re-directing non-visible wavelengths of sunlight incident on or passing through the light receiving surface in a direction generally transverse to a plane of the unit toward structure for collection by the one or more photovoltaic cells; and
one or more electrically powered devices within the cavity and arranged to receive
electrical power generated by the one or more photovoltaic cells.

2. A building unit comprising:
first and second light transmissive panels, the first panel defining a light receiving surface;
a structure supporting the panels in a spaced apart relationship to form a cavity therebetween;
one or more photovoltaic cells disposed within the cavity adjacent the structure;
an arrangement supported by the structure for re-directing non-visible wavelengths of sunlight incident on or passing through the light receiving surface in a direction generally transverse to a plane of the unit toward structure for collection by the one or more photovoltaic cells; and
a rechargeable electrical energy storage device coupled with the one or more photovoltaic cells wherein the storage device is arranged to power one or more electrical devices located
inside or outside of the cavity.

3. A building unit comprising:
first and second light transmissive panels, the first panel defining a light receiving surface;
a structure supporting the panels in a spaced apart relationship to form a cavity therebetween, the structure extending along at or near a perimeter of the building unit;
one or more photovoltaic cells disposed within the cavity for producing electrical energy from light passing through the light receiving surface, the one or more photovoltaic cells positioned so as to extend along at or adjacent one or more edge regions of the structure so as to define at least in part a central area of the building unit which corresponds to an area in or adjacent which no photovoltaic cells are positioned and which is at least largely transmissive for light, the positioning of the one or more photovoltaic cells facilitating same receiving or collecting sunlight incident on or passing through the light receiving surface and which is directed or internally reflected toward the relevant edge region(s) of the structure;
a rechargeable electrical energy storage device coupled with the one or more photovoltaic cells for storing the electrical energy wherein the storage device is arranged to power one or
more electrical devices located inside or outside of the cavity;
a controller arranged to control operation of one or more of the electrically powered devices in an autonomous or remote manner, the controller arranged in network communication with a computing device so that operation of the controller in the autonomous or remote manner is selectable remotely via the computing device, at least one of the or each electrically powered devices arranged operable for modifying transmission of light from the building unit; and
one or more sensors operatively associated with the controller;
wherein the controller is configured to remotely control the relevant of the or each electrically powered device(s) for controllably adjusting light transmission characteristic(s) of the building unit for varying an intensity and/or colour of light transmitted therefrom in response to instructions received from a user of the computing device, and to autonomously control the relevant of the or each electrically powered device(s) for controllably adjusting light transmission characteristic(s) of the building unit for varying an intensity and/or colour of light transmitted therefrom in response to information received from the or each sensor(s) or based on one or more criteria set by the user.

4. The building unit according to claim 3 wherein the rechargeable electrical energy storage device is a supercapacitor or a rechargeable battery.

5. The building unit according to claim 3 wherein, when located inside the cavity, at least one of the electrically powered devices is operable to vary or otherwise control an effect of solar radiation incident on the light receiving surface.

6. The building unit according to claim 3 wherein the one or more electrically powered devices comprises any one or a combination of any two or more of: a blind, a curtain, an air damper, a fan, an electrochromic, polymer-dispersed liquid crystal (PDLC), LCD, electrophoretic, E-ink or other electrically activated dynamic layer or coating, a motor, a ventilation system, and a pump.

7. The building unit according to claim 6 wherein one or more of the sensors are operatively associated with the one or more electrically powered devices wherein the one or more sensors are arranged to automatically operate the devices when a threshold level of a sensed parameter is crossed or wherein the one or more sensors are arranged to provide information to the controller pertaining to an effect or characteristic of solar radiation passing through the light receiving surface.

8. The building unit according to claim 3 wherein the one or more sensors comprise any one or a combination of any two or more of: a temperature sensor, a light sensor, a rain sensor, an air quality sensor, a CO sensor, CO2 sensor, a humidity sensor, an ambient light sensor, a battery charge sensor and a facial or gait recognition sensor.

9. The building unit according to claim 6 wherein the one or more electrically powered devices comprise a blind which is operable between an open condition in which transmission of at least a portion of incident light through the building unit is enabled and a closed condition in which transmission of at least a majority of incident light through the building unit is obstructed by the blind.

10. The building unit of claim 9 wherein the blind comprises portions arranged to obstruct transmission of the light when the blind is in the closed condition and which comprise photovoltaic cells facing towards the light receiving surface when the blind is in the closed condition.

11. The building unit according to claim 3 comprising a suspended coated film positioned between the first and second panels.

12. The building unit according to claim 3 wherein the at least one or more photovoltaic cells comprise bifacial photovoltaic cells.

13. A building system comprising:
at least one building unit according to claim 3; and
a controller arranged in network communication with the at least one building unit;
wherein the controller is arranged to control operation of one or more of the electrically powered devices of the at least one building unit.

14. The building system according to claim 13, wherein one or more of the sensors of the at least one building unit are operatively associated with the one or more electrically powered devices wherein the sensors are arranged to automatically operate the devices when a threshold level of a sensed parameter is crossed or wherein the sensors are arranged to provide information to the controller pertaining to an effect or characteristic of solar radiation passing through the light receiving surface; and
wherein the controller is arranged to receive sensor data from the one or more sensors and to control operation of one or more of the electrically powered devices of the at least one building unit using the sensor data.

15. The building system according to claim 14 wherein the controller is arranged to determine whether the sensor data exceeds a respective threshold level and, if a threshold is exceeded, to automatically send a control signal to one or more of the at least one building unit to modify operation of one or more of the electrically powered devices.

16. The building system according to claim 13 wherein the controller is in wireless communication with the at least one building unit and is implemented remotely using a cloud computing service platform.

17. The building system according to claim 14 wherein the controller is further arranged to receive external information and to control operation of one or more of the electrically powered devices of the at least one building unit using the sensor data and the external information.

18. The building system according to claim 13 wherein the controller is arranged to autonomously control the operation of one or more of the electrically powered devices of the at least one building unit using machine learning.

19. A building unit comprising:
first and second light transmissive panels, the first panel defining a light receiving surface;
a structure supporting the panels in a spaced apart relationship to form a cavity therebetween, the structure extending along at or near a perimeter of the building unit;
one or more photovoltaic cells disposed within the cavity for producing electrical energy from light passing through the light receiving surface, the one or more photovoltaic cells positioned so as to extend along at or adjacent one or more edge regions of the structure so as to define at least in part a central area of the building unit which corresponds to an area in which no photovoltaic cells are positioned and which is at least largely transmissive for light, the positioning of the one or more photovoltaic cells facilitating same receiving or collecting sunlight incident on or passing through the light receiving surface and which is directed or internally reflected toward the relevant edge region(s) of the structure;
a rechargeable electrical energy storage device coupled with the one or more photovoltaic cells for storing the electrical energy wherein the storage device is arranged to power one or
more electrical devices located inside or outside of the cavity;
a controller arranged to control operation of one or more of the electrically powered devices in an autonomous or remote manner, remote control of the operation of the one or more of electrically powered devices by the controller being carried out via operation of the computing device configured to be network communicable with the controller, at least one of the or each electrically powered devices arranged operable for modifying transmission of light from the building unit; and
one or more sensors operatively associated with the controller;
wherein the controller is configured to remotely control the relevant of the or each electrically powered device(s) for controllably adjusting light transmission characteristic(s) of the building unit for varying an intensity and/or colour of light transmitted therefrom in response to instructions received from a user of the computing device, and to autonomously control the relevant of the or each electrically powered device(s) for controllably adjusting light transmission characteristic(s) of the building unit for varying an intensity and/or colour of light transmitted therefrom in response to information received from the or each sensor(s) or based on one or more criteria set by the user.
